(19) United States
(12) Patent Application Publication
(10) Pub. No.: US 2010/0319754 A1
(43) Pub. Date: Dec. 23, 2010

(54) PHOTOVOLTAIC MODULE CONFIGURATION

(76) Inventors: Basha S. Sajjad, Pleasanton, CA (US); Shmuel Erez, San Jose, CA (US); S. Daniel Miller, San Jose, CA (US); Mahendran T. Chidambaram, Saratoga, CA (US); Ravi Vellanki, San Jose, CA (US); Gerald Schock, Campbell, CA (US)

Correspondence Address: SNR DENTON US LLP, P.O. BOX 061080, CHICAGO, IL, 60606-1080, US

(21) Appl. No.: 12/709,350

(22) Filed: Feb. 19, 2010

Related U.S. Application Data
(60) Provisional application No. 61/153,962, filed on Feb. 19, 2009.

(51) Int. Cl. H01L 31/052; H01L 31/048; H01L 31/18

(52) U.S. Cl. 136/246; 136/251; 156/292

(57) ABSTRACT

Improvements for a photovoltaic module (PVM) include the use of a micro-embossed, reflective optical film located in areas of the PVM not covered by the solar cells. The optical film is configured to reflect light incident upon the PVM onto the solar cells and may be formed from a polymeric material. Further enhancements include the use of a compliant heat conducting polymeric film on back sides of the solar cells and a heat conductive polymeric film deposited on an aluminum foil to form a composite film, which effects heat transfer from the solar cell junctions and improves cell efficiency. A top glass with selective frequency and anti-reflective coatings may also be used. Further, improved interconnects for the solar cells eliminate sharp edges, helping to avoid any potential for encapsulant tearing or tab “push-through” and resultant shorting during lamination.

### RELATED APPLICATION

This is a NONPROVISIONAL of and claims priority to U.S. Provisional Patent Application 61/153,962, filed 19 Feb. 2009, which is incorporated herein by reference.

### FIELD OF THE INVENTION

This invention relates to photovoltaic modules made up of solar cells made from mono-crystal or poly-crystal silicon wafers of various sizes and/or shapes or any other semiconductor material of any size and/or shape.

### BACKGROUND

Traditionally, photovoltaic modules made from mono-crystal or poly-crystal silicon wafers, interconnected electrically for voltage and power ratings, of different thicknesses, sizes and shapes or any other semiconductor material, are fabricated using a double bag laminating technique in the configuration described below and illustrated in FIG. 1.

A typical photovoltaic module (PVM) includes solar cells that are electrically interconnected and are laminated to a clear glass substrate with the collector side of the solar cell facing the glass with a compliant polymeric film such as Ethylene Vinyl Acetate (EVA) film on either side of the solar cell and a denser film, such as Polyvinyl Fluoride (PVF), also known as Tedlar™, providing protection to solar cells from the harsh environmental conditions and to meet specifications such as IEC 61215 or any other specifications related to photovoltaic module test and qualification. FIG. 12 illustrates a typical, conventional PVM configuration. Tedlar film may also be used in a Tedlar-Polyester-Tedlar sandwich configuration. Tinned copper foil of uniform thickness and width is used for interconnecting the cells back and forth.

PVMs are typically fabricated in the above mentioned configurations, or other configurations, using a double bag vacuum lamination technique using a laminator under specific pumping cycle, time, temperature, pressure and related process conditions. The PVM so laminated is framed in a suitable metallic extruded profile with a polymeric barrier for protection from environmental conditions to satisfy IEC 61215 specifications for test and qualification requirements. This conventional configuration for photovoltaic modules has a fixed efficiency determined under standard testing conditions for the photovoltaic module industry. The efficiency of the photovoltaic module is dependent on the solar cell efficiency, the cell layout configuration and the materials used in the fabrication of photovoltaic module.

### SUMMARY OF THE INVENTION

Various improvements for PVMs are described herein. For example, the present invention includes a PVM which includes a micro-embossed reflective film located in-between rows of solar cells in the PVM and in areas of the PVM not covered by the solar cells, wherein the optical film entraps light incident upon the module, thereby improving overall output efficiency of the module. The micro-embossed optical film may be formed from a polymeric material having different physical, thermal and optical characteristics than an EVA film which is used as encapsulant for the module. For example, the micro-embossed optical film may be characterized by not deforming at temperatures where an EVA file softens and flows, and thereby retains geometric features embossed on the optical film. Further, the optical film may be UV stabilized. In one particular embodiment, the optical film comprises Polymethyl Methacrylate (PMMA). In various embodiments, the micro-embossed optical film may be fabricated as a continuous length roll of film with optical micro-structures at locations to cover areas not covered by the solar cells in the module. In some instances, the micro-embossed optical film is placed behind the solar cells with an active micro-optical film facing a glass side of the module and overlapping back sides of the solar cells. A non-active area of the optical film includes suitably sized holes so that the EVA encapsulant or the heat conductive plastic film or the heat conductive encapsulant film or doped EVA heat conductive encapsulant located on the back sides of the solar cells passes through the holes in the micro-embossed optical film and adheres to the back sides of the solar cells to provide adequate bonding strength during a lamination process.

A further embodiment of the invention provides a PVM that includes a compliant heat conducting polymeric film on back sides of solar cells of the module. The PVM may further include a heat conductive polymeric film deposited on an aluminum foil to form a composite film, which composite film comprises a rear barrier film, whereby effective heat transfer from the solar cell junctions through conduction and then through convection heat transfer provides an increase in cell efficiency.

Still further embodiments of the present invention provide a rigid crystalline PVM whose construction process uses conventional technologies, as described above, but the structure of which is modified in one or more of the following ways to improve the module output efficiency:
A. A conformal hard coating is introduced on top of the top glass to allow greater amounts of the convertible light to pass through but to also limit the amount of high ultra violet and infra-red light that the solar cells convert to heat.
B. Reflective film structures designed to reflect back the light to the solar cells that lands within the module but outside or between the rigid PV solar cells within the module may be used.
C. A replacement for, or modifications to, conventional EVA back encapsulants that greatly increases the thermal conductivity of the encapsulant may be introduced, thereby increasing the efficiency of the cells and the output of the module for a given cell, and reducing the cost per installed Watt;
D. A polymeric or polymer-metal hybrid replacement for the PVF or functionally similar backsheet currently used in module manufacturing may be used, thereby greatly increasing the thermal conductivity of the encapsulant, increasing the efficiency of the cells and the output of the module for a given cell, and reducing the cost per installed Watt.

The rigid crystalline PVM may also include a micro-embossed reflective metallic or reflective coated plastic optical film of suitable design that forms a lattice, installed so that the cross-members of said lattice are between the rows and columns of solar cells in the PVM, mounted in conjunction with the solar cells between the front and rear encapsulant layers. The optical film is used to entrap the incident light that strikes the gaps between the cells in the PVM and reflects it back to the surface of the solar cells to be reabsorbed, thus increasing light conversion efficiency and, as a result, increasing the output efficiency of any given rigid cell PVM.

Alternatively, the PVM may include a micro-embossed, solid sheet, reflective coated, plastic optical film that is mounted behind the solar cells but is mounted in conjunction with the solar cells between the front and rear encapsulant layers. A thin EVA layer is bonded to the face of the micro-embossed film to enhance bonding to the back of the PV cells. The design of the embossing is now such that the portion of the film that is visible between the cells has embossing of such a direction and angle that the light that strikes the film is reflected back onto the cells. The optical film is used to entrap the incident light that strikes the gaps between the cells in the PVM, thus increasing light conversion efficiency and, as a result, increasing the output of any given rigid cell PVM.

Alternatively, the PVM may include a micro-embossed, solid sheet, reflective, coated, plastic optical film that is mounted behind rear encapsulant, thus behind the cells, taking advantage of the fact that both the cells and the back encapsulant layer, once the module has been laminated, are extremely thin. The design of the embossing is now such that the portion of the film that is visible between the cells has embossing of such a direction and angle that the light that strikes the film is reflected back onto the cells. The optical film is used to entrap the incident light that strikes the gaps between the cells in the PVM, thus increasing light conversion efficiency and, as a result, increasing the output of any given rigid cell PVM.

The reflective coated, micro embossed polymeric optical film used in any of the above-described configurations is preferably flexible, but has thermal and physical properties that allow it to retain its basic structure during the heating and pressure of the module lamination step. At the softening and flowing temperatures of EVA, the embossing structures of said optical film are not physically deformed so that the light entrapment layer of the modules used in the above-described configurations survives intact beyond the module lamination process. This film may also be ultra violet-stabilized. A typical such plastic is a member of the polycarbonate family, as this has the requisite working temperature and strength without excessive rigidity, but the present invention is not limited to the use of this material.

The micro-embossed polymeric optical film may be fabricated as continuous length roll of film using a conventional pressure roller techniques, with one of the two rollers having negative images of the micro-structures etched therein so that the micro-structures are embossed into the film during manufacturing. The non-active area of the optical film may be punched with suitably sized holes so that the EVA encapsulant or the heat conductive plastic film or the heat conductive encapsulant film or doped EVA heat conductive encapsulant located on the back side of the solar cells pass through the holes in the optical film and adhere to the back sides of the solar cells to provide adequate bonding during the lamination process.

In embodiments of a PVM configured in accordance with the present invention, different layers of the polymeric films that are initially behind the solar cells may be selectively embossed in a way that all the films, including the micro-embossed optical film, protrude to the same level of the solar cell front surface in the area between adjacent solar cells (i.e., along the width and length of the cells) without damaging the solar cells or the interconnect. This may be done by pre-forming the layers or by introducing an embossing plate that forms the structures during the lamination process.

Embodiments of the present PVM may replace the Tedlar PVF or functionally equivalent backsheet with an electrically insulating, thermally conductive polymeric film. This film provides the atmospheric and structural needs of the module in place of the PVF or similar film. This provides significant improvement in cooling by increasing the conductivity of the polymeric package in which the cells are trapped. Effective heat transfer from the solar cell junction through conduction and then through convection heat transfer is the reason for increase in cell efficiency. Alternatively, the Tedlar PVF or functionally equivalent backsheet may be replaced with (i) a composite film made of an electrically insulating, thermally conductive polymeric film deposited on an aluminum, copper or similar thermally conductive, corrosion resistant metal foil, (ii) a composite film made of an electrically insulating, thermally conductive polymeric film deposited on an aluminum, copper or similar thermally conductive, corrosion resistant metal foil, to which is bonded an aluminum honeycomb structure, or (iii) a pre-formed thermoplastic designed to allow cells and solder tabs (or, where appropriate, back-side interconnects) to fit into predesigned pockets. The thermally conductive thermoplastics may be produced from elastomeric materials with suitable additives and fillers. The electrical resistivity is typically in the range 10¹² to 10¹⁶ Ω-cm, while the thermal conductivity of thermally conductive plastics can easily exceed 10 W/mK, significantly higher than materials normally incorporated in conventional PV solar modules. The preformed thermoplastic backsheet is coated with a very thin layer of traditional EVA, providing a bonding surface for the cells and the top EVA, allowing elimination of the back EVA layer used in conventional modules.

Further, embodiments of the present PVM may replace the back EVA layer of conventional modules with a modified EVA encapsulant layer in which the EVA has been doped or modified with appropriate materials to improve the heat conduction on the back side of the cells. This enables greatly improved heat transfer while maintaining the EVA's primary purpose of encapsulation, improving the functional efficiency of the cells and the output of the module. Alternatively, the back EVA layer of the conventional modules may be replaced with an opaque encapsulant layer in which the replacement encapsulant has been doped or modified with appropriate materials to improve the heat conduction on the back side of the cells. This enables greatly improved heat transfer while maintaining the encapsulant's cell protection properties, improving the functional efficiency of the cells and the output of the module.

In some instances, a PVM according to the present invention will have a top glass layer (often, but not exclusively, made of crown glass) coated with selective frequency coatings to reduce infra-red radiation and undesirable ultraviolet light (which reduces that portion of the solar radiation spectrum that is only poorly converted to electricity, if it is converted at all). In addition, this coating may have anti-reflective properties. While a typical range that the frequency selective filtration would allow might be 450 nm to 1200 nm, the specific frequency range may be tuned for the cells to be used in the module. Multi-junction cells, for example, may benefit from a broader range of available energy passed through, while black-Si cells will benefit from a lower frequency cut-off (because black-Si cells provide improved conversion efficiency in the infra-red range).

In some cases, interconnect tabs for the front half and the rear half of the PVM are of two different widths to facilitate bonding of tabs between the cells and reduce the potential for encapsulant tearing or tab “push-through” and resultant shorting during lamination. In some cases, the cross section of the interconnect tabs may be curvilinear, instead of a flat ribbon, to eliminate sharp edges, helping to avoid any potential for encapsulant tearing or tab “push-through” and resultant shorting during lamination.

Various embodiments of PVMs in accordance with the present invention may include an aluminum honeycomb structure suitably bonded to an aluminum foil, so as to enhance heat transfer and lower operating temperature of the solar cells of the module.

These and further embodiments of the invention are described below.

### BRIEF DESCRIPTION OF THE DRAWINGS

Embodiments of the present invention are illustrated by way of example, and not limitation, in the figures of the accompanying drawings, in which:

FIGS. 1-9 illustrate various PVMs configured in accordance with various embodiments of the present invention. In these illustrations, items 1, 2 and 3, are, respectively, a top glass, an EVA encapsulating film and the solar cells. Where present, item 4 is a rear EVA film, item 5 is an embossed micro-optical film, item 6 is a thermally conductive polymer, and item 7 is an aluminum or other metal foil, in some instances with an additional structure.

FIG. 10 illustrates differences in cross-section between front side and back side interconnect tabs in accordance with embodiments of the present invention.

FIG. 11 illustrates differences in cross-section between conventional interconnect tabs and interconnect tabs configured in accordance with embodiments of the present invention.

FIG. 12 illustrates a conventional PVM configuration.

FIG. 13 illustrates a mechanism to achieve total internal reflection.

FIG. 14 illustrates an example of a laminated PVM.

### DETAILED DESCRIPTION

One aspect of the present invention addresses issues inherent in conventional photovoltaic modules, namely, effective utilization of the photon energy radiating on the photovoltaic module and the degradation of solar cell efficiency as heat builds up in the solar cell, thereby reducing the module efficiency.

Some of the light energy falling on a photovoltaic panel is reflected back to the environment. Hence, the available light energy is not fully utilized. Packing density of the photovoltaic module depends on the size and shape of the solar cells, the gap between the cells within a row and the gap between individual rows of cells. A finely embossed polymeric film of suitable compatible material placed in the panel area not covered by the solar cells can act to entrap the light incident thereon, thereby gaining a light utilization advantage and increasing the output efficiency of the solar cell relative to the conventional photovoltaic module configuration. FIG. 13 illustrates a mechanism to achieve total internal reflection.

The efficiency of solar cell operation also drops with entrapment of heat in a photovoltaic module. One of the reasons for this is attributable to the various materials used in the manufacture of the photovoltaic module to meet the requirements of IEC 61215 specifications. Glass, EVA film and PVF or Tedlar films are relatively good thermal insulators. The heat generated in the module is trapped and accumulated, thereby increasing the operating temperature of the solar cell. That, in turn, affects the efficiency of the solar cell (typically reducing the efficiency thereof). A thermally conductive film positioned behind the solar cell, which may be a thermally conductive equivalent to the EVA encapsulant in the back of the solar cell, will provide an effective path for heat conduction away from the solar cell. Conductive polymeric film thermally coupled to large area conductive films promoting convective heat transfer will reduce the operating temperature of the solar cell and, hence, enhance cell efficiency.

FIG. 1 illustrates a photovoltaic module (PVM) configured in accordance with one embodiment of the present invention. Items 1, 2 and 3, namely the top glass, EVA encapsulating film and the solar cells which are interconnected front to back or via an all back connection, are as found in conventional photovoltaic modules. Item 4, which is a rear EVA film, is thinner than that found in conventional modules. Item 5 is an embossed micro-optical film with features for trapping light and is not found in conventional modules. It may be made from suitable electrically insulating, thermally conductive polymeric material or other thermally conductive material, and may have a thicknesses of a few micrometers. It may be coated with mica or a similar reflective material. Item 6 is a thermally conductive polymer with additives to promote heat conduction, and is not found in conventional modules. If the dielectric strength of the layer in item 5 is sufficient to provide insulation and to pass IEC arc testing requirements, then this layer can be electrically conductive, but it must act as a bonding layer for item 7. Item 7, which replaces conventional Tedlar film, may be an aluminum foil or equivalent thermally conductive metal foil that resists corrosion.

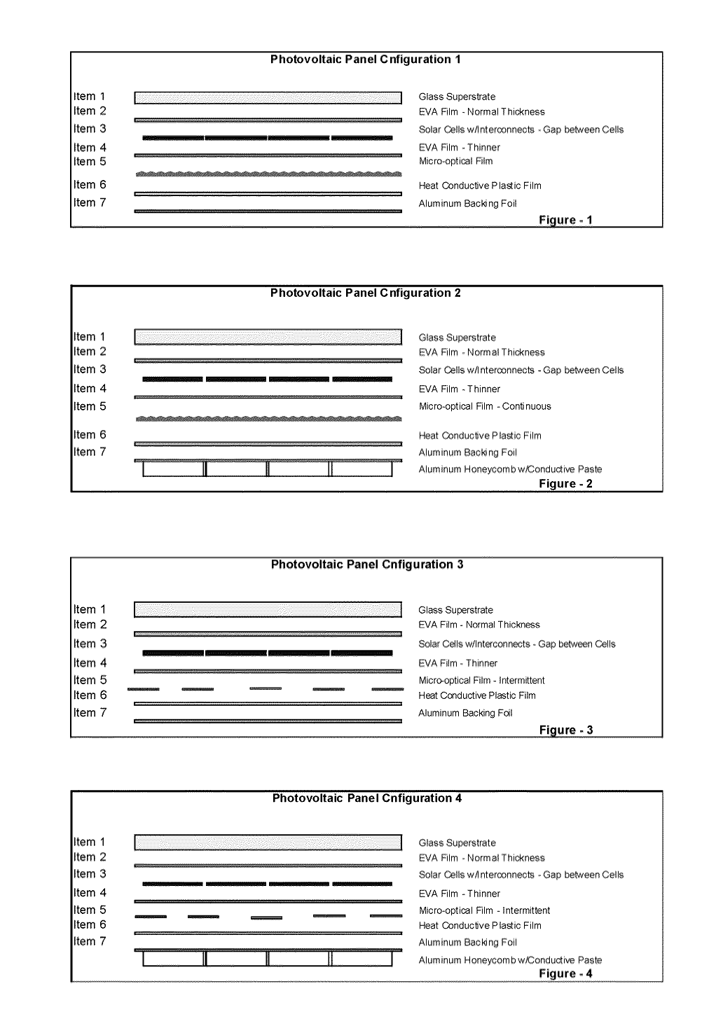

FIG. 2 illustrates a photovoltaic module configured in accordance with a further embodiment of the present invention. Items 1, 2 and 3, the top glass, EVA encapsulating film and the solar cells which are interconnected front to back or via an all back connection, are as found in conventional modules. Item 4 is a rear EVA film and is thinner than that found in conventional modules. Item 5 is an embossed micro-optical film with features for trapping light and is not found in conventional modules. It may be made from suitable electrically insulating, thermally conductive polymeric material or other thermally conductive material, and may have a thickness of a few micrometers. This layer will be coated with mica or a similar reflective material. Item 6 is a heat conductive polymer with additives to promote heat conduction, and is not found in conventional modules. If the dielectric strength of the layer in item 5 is sufficient to provide insulation and to pass IEC arc testing requirements, then this layer can be electrically conductive, but it must act as a bonding layer for item 7. Item 7 replaces Tedlar film in conventional modules and may be an aluminum foil with an additional aluminum honeycomb structure for convective heat transfer.

FIG. 3 illustrates a photovoltaic module configured in accordance with yet another embodiment of the present invention. Items 1, 2 and 3, the top glass, EVA encapsulating film and the solar cells which are interconnected front to back or all back connection, are as found in conventional modules. Item 4 is a rear EVA film and is thinner than that found in conventional modules. Item 5 is an embossed micro-optical film with features for trapping light and is not found in conventional modules. It may be make from suitable electrically insulating polymeric material, and may have a thickness of a few micrometers. This film will be coated with a mica or similar reflective material but does not cover the entire area of the photovoltaic module. Rather it covers only the area not covered by the solar cells (i.e., the gaps between the cells) and, where present, the kerf-cut corners of the cells, leaving areas under the cells exposed. Item 6 is a thermally conductive, electrically insulating polymer with additives to promote heat conduction, and is not found in conventional modules. Item 7 replaces the Tedlar film in conventional modules and may be an aluminum foil or equivalent thermally conductive metal foil that resists corrosion.

FIG. 4 illustrates a photovoltaic module configured in accordance with yet a further embodiment of the present invention. Items 1, 2 and 3, the top glass, EVA encapsulating film and the solar cells which are interconnected front to back or via an all back connection, are as found in conventional modules. Item 4 is a rear EVA film and is thinner than that found in conventional modules. Item 5 is an embossed micro-optical film with features for trapping light and is not found in conventional modules. It may be made from suitable electrically insulating polymeric material, and may have a thickness of a few micrometers. This film will be coated with mica or a similar reflective material but does not cover the entire area of the photovoltaic module. Rather it covers only the area not covered by the solar cells (i.e., gaps between the cells) and, where present, the kerf-cut corners of the cells, leaving the areas under the cells exposed. Item 6 is a thermally conductive, electrically insulating polymer with additives to promote heat conduction, and is not found in conventional modules. Item 7 replaces the Tedlar film in conventional modules and may be an aluminum foil with an additional aluminum honeycomb structure for convective heat transfer.

FIG. 5 illustrates a photovoltaic module configured in accordance with still a further embodiment of the present invention. Items 1, 2 and 3, the top glass, EVA encapsulating film and the solar cells which are interconnected front to back or via an all back connection, are as found in conventional modules. Item 4, the rear EVA film, has been eliminated. Item 5 is an embossed micro-optical film with features for trapping light and is not found in conventional modules. It may be made from suitable electrically insulating polymeric material, and may have a thickness of a few micrometers. This film is coated with mica or a similar reflective material but does not cover the entire area of photovoltaic module. Rather it covers only the area not covered by the solar cells (i.e., gaps between the cells) and, where present, the kerf-cut corners of the cells, leaving areas under the cells exposed. Item 6 is a thermally conductive, electrically insulating polymer with additives to promote heat conduction, and is not found in conventional modules. It acts as both the bonding layer for item 7 and the back encapsulating material for the solar cells (item 3) and is made of a suitable material. If the dielectric strength of the layer in item 5 is sufficient to provide insulation and to pass IEC arc testing requirements, then this layer can be electrically conductive, but it must act as a bonding layer for item 7. Item 7 replaces the Tedlar film found in conventional modules and may be an aluminum foil with an additional aluminum honeycomb structure for effective heat transfer.

The manufacturing process for laminating the PVM may include supplemental embossing of the laminate structure so that the reflective structures of the embossed micro-optical film described above are raised to the same level as the surface of the solar cells (i.e., they are in line with the solar cell top side facing the light rays). This embossing during the lamination process must be done such that only the portion of the micro-optical film in line with the gaps in the solar cell are raised to the level of the face of the cells, even if the micro-optical film is also present under the cells. Care must be taken so that no damage to the solar cells (layer item 3) or the back structure materials of the module (layer items 4 through 7) are damaged. The design and installation of the embossed micro-optical film must be such that the optical reflective features of the film are oriented so that the features face the sun's rays when the active top face of the solar cell is facing the sun rays.

The embossed cross-section is illustrated in FIG. 14. In this illustration, item 1 is a glass substrate, item 2 is an EVA film of conventional thickness, item 3 is interconnected solar cells, item 4 is the optional, thin, EVA film, item 5 is the embossed micro-optical film, polymeric or conductive, item 6 is the heat conductive polymeric film, and item 7 is the aluminum foil, with or without the optional aluminum honeycomb structure.

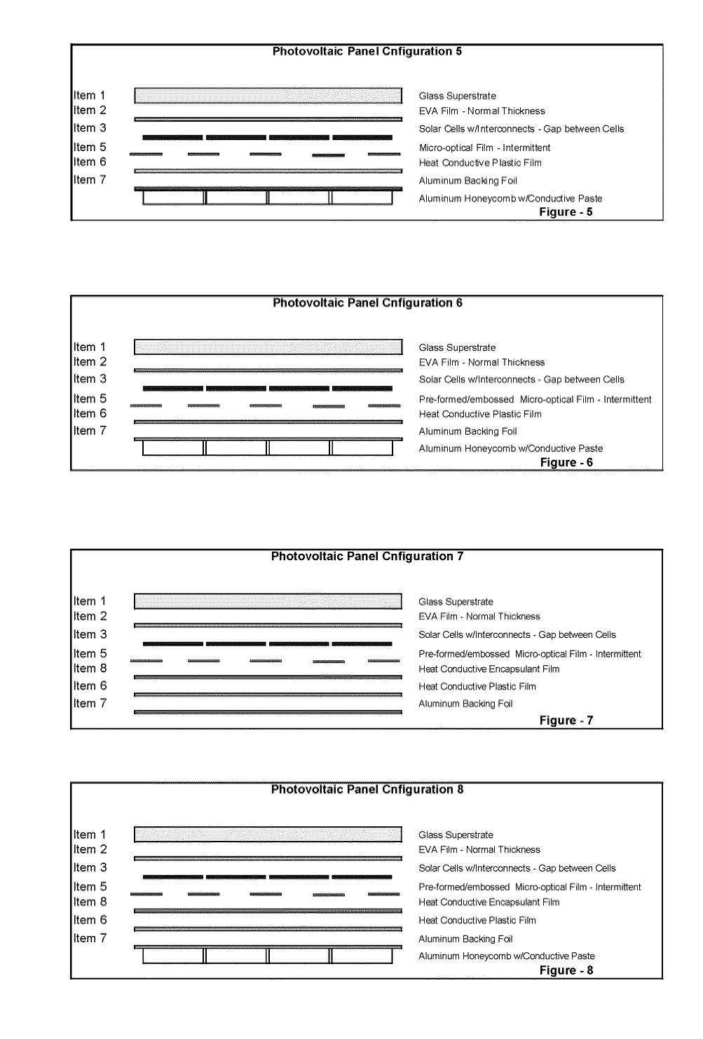

FIG. 6 illustrates a photovoltaic module configured in accordance with still another embodiment of the present invention. Items 1, 2 and 3, the top glass, EVA encapsulating film and the solar cells which are interconnected front to back or via an all back connection, are as found in conventional modules. Item 4, the rear EVA film, has been eliminated. Item 5 is an embossed micro-optical film with features for trapping light and is not found in conventional modules. It may be made from suitable electrically insulating polymeric material, and may have a thickness of a few micrometers. This film is coated with mica or a similar reflective material but does not cover the entire area of photovoltaic module. Rather only the area not covered by the solar cells (i.e., the gaps between the cells) and, where present, the kerf-cut corners of the cells is covered, leaving the areas under the cells exposed. In this embodiment, the film is pre-formed or embossed in a U-channel shape to fit into the gap between the solar cells so that the embossed micro-optical structure is in the same plane as the solar cell top surface. Item 6 is a thermally conductive, electrically insulating polymer with additives to promote heat conduction, and is not found in conventional modules. Item 6 must act as both the bonding layer for item 7 and the back encapsulating material for the solar cells (item 3), and must be of a suitable material. Item 7 replaces the Tedlar film in conventional module and may be an aluminum foil with an additional aluminum honeycomb structure for effective heat transfer.

FIG. 7 illustrates a photovoltaic module configured in accordance with yet another embodiment of the present invention. Items 1, 2 and 3, the top glass, EVA encapsulating film and the solar cells which are interconnected front to back or via an all back connection, are as found in conventional modules. Item 4, the rear EVA film, has been eliminated. Item 5 is an embossed micro-optical film with features for trapping light and is not found in conventional modules. It may be made from suitable electrically insulating polymeric material, and may have a thickness of a few micrometers. This film is coated with mica or a similar reflective material but does not cover the entire area of photovoltaic module. Rather, it covers only the area not covered by the solar cells (i.e., gaps between the cells) and, where present the kerf-cut corners of the cells, leaving the areas under the cells exposed. In this embodiment, the film is pre-formed or embossed in a U-channel shape to fit into the gap between the solar cells so that the embossed micro-optical structure is in the same plane as the solar cell top surface. Item 6 is a very thin (less than 100 microns) electrically insulating polymer, and is not found in conventional modules. Item 7 replaces the Tedlar film in conventional module and may be an aluminum foil. Item 8 is a doped or otherwise modified encapusant film which is heat conductive (and which may also be electrically conductive), and is not found in conventional modules.

FIG. 8 illustrates a photovoltaic module configured in accordance with still a further embodiment of the present invention. Items 1, 2 and 3, the top glass, EVA encapsulating film and the solar cells which are interconnected front to back or via an all back connection, are as found in conventional modules. Item 4, the rear EVA film, has been eliminated. Item 5 is an embossed micro-optical film with features for trapping light and is not found in conventional modules. It may be made from suitable electrically insulating polymeric material, and may have a thickness of a few micrometers. This film is coated with mica or a similar reflective material but does not cover the entire area of photovoltaic module. Rather it covers only the area not covered by the solar cells (i.e., the gaps between the cells) and, where present, the kerf-cut corners of the cells, leaving the areas under the cells exposed. In this embodiment, the film is pre-formed or embossed in a U-channel shape to fit into the gap between the solar cells so that the embossed micro-optical structure is in the same plane as the solar cell top surface. Item 6 is a very thin (less than 100 microns) electrically insulating polymer, and is not found in conventional modules. Item 7 replaces the Tedlar film in conventional module and may be an aluminum foil with an additional aluminum honeycomb structure for effective heat transfer. Item 8 is a doped or otherwise modified encapusant film which is heat conductive (and may also be electrically conductive), and is not found in conventional modules.

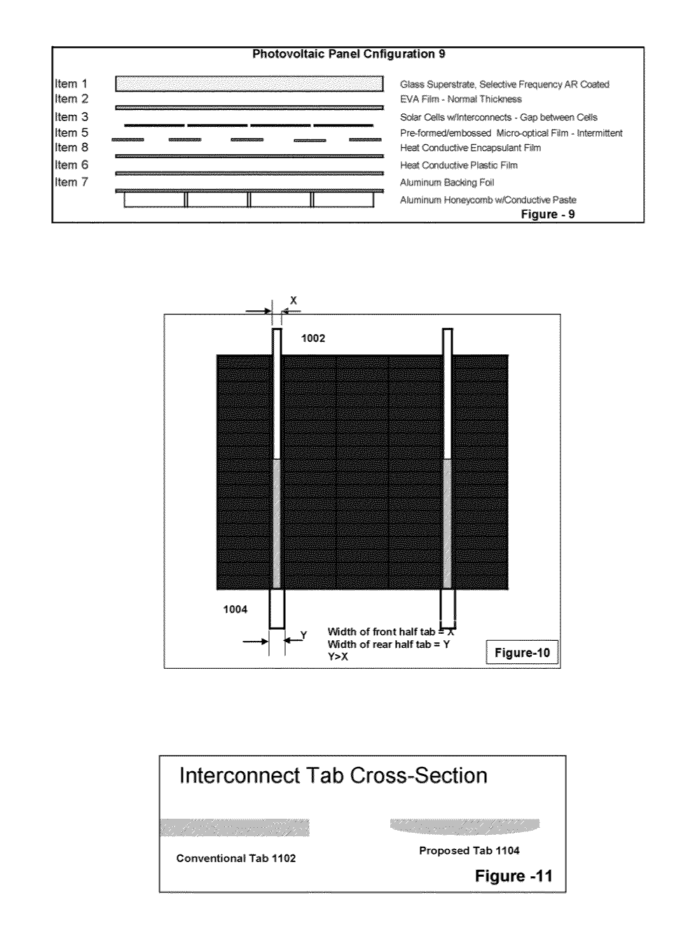

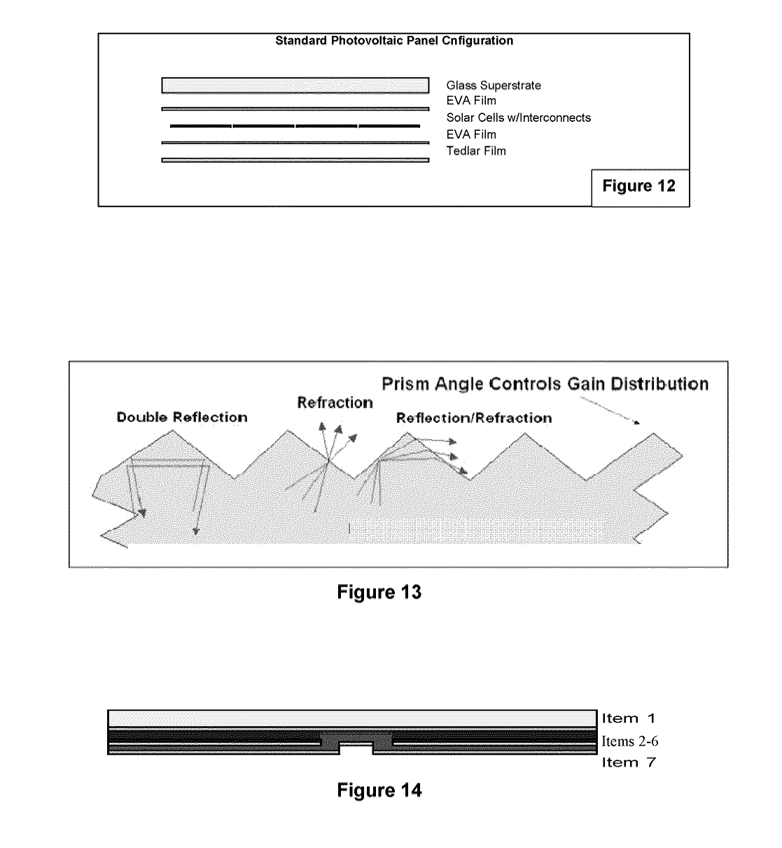

FIG. 9 illustrates a photovoltaic module configured in accordance with yet a further embodiment of the present invention. Item 1 replaces the conventional glass superstrate with a glass that provides both anti-reflective (AR) properties and selective filtering that allows only light to pass within a specified band. The band limitations are chosen so that a monocrystalline Si cell will have a different band-pass limit than would a multi-junction cell Items 2 and 3, the EVA encapsulating film and the solar cells which are interconnected front to back or va an all back connection, are as found in conventional modules. Item 4, the rear EVA film, has been eliminated. Item 5 is an embossed micro-optical film with features for trapping light and is not found in conventional modules. It may be made from suitable electrically insulating, thermally conductive polymeric material or conductive material, and may have a thickness of a few micrometers. This film is coated with mica or a similar reflective material. Item 6 is a heat conductive polymer with additives to promote heat conduction, and is not found in conventional modules. Item 7 replaces the Tedlar film in conventional module and may be an aluminum foil with an additional aluminum honeycomb structure for effective heat transfer. Item 8 is a doped or otherwise modified encapusant film which is heat conductive, and is not found in conventional modules.

Although this detailed description contains a discussion of many specific features of embodiments of the present invention, these features should not be construed as limiting the scope of the invention but merely as illustrating different examples and aspects of the invention. It should be appreciated that the scope of the invention includes other embodiments not discussed in detail above. Various modifications, changes and variations which will be apparent to those skilled in the art may be made in the arrangement, operation and details of the above-described methods and apparatus of the present invention without departing from the spirit and scope of the invention.

For example, the present invention includes a PVM conforming to any of the above-described embodiments and which includes a micro-embossed reflective film located in-between rows of solar cells in the PVM and in areas of the PVM not covered by the solar cells, wherein the optical film entraps light incident upon the module, thereby improving overall output efficiency of the module. The micro-embossed optical film may be formed from a polymeric material having different physical, thermal and optical characteristics than an EVA film which is used as encapsulant for the module. For example, the micro-embossed optical film may be characterized by not deforming at temperatures where an EVA file softens and flows, and thereby retains geometric features embossed on the optical film. Further, the optical film may be UV stabilized. In one particular embodiment, the optical film comprises Polymethyl Methacrylate (PMMA). In various embodiments, the micro-embossed optical film may be fabricated as a continuous length roll of film with optical micro-structures at locations to cover areas not covered by the solar cells in the module. In some instances, the micro-embossed optical film is placed behind the solar cells with an active micro-optical film facing a glass side of the module and overlapping back sides of the solar cells. A non-active area of the optical film includes suitably sized holes so that the EVA encapsulant or the heat conductive plastic film or the heat conductive encapsulant film or doped EVA heat conductive encapsulant located on the back sides of the solar cells passes through the holes in the micro-embossed optical film and adheres to the back sides of the solar cells to provide adequate bonding strength during a lamination process.

A further embodiment of the invention provides a PVM that includes a compliant heat conducting polymeric film on back sides of solar cells of the module. The PVM may further include a heat conductive polymeric film deposited on an aluminum foil to form a composite film, which composite film comprises a rear barrier film, whereby effective heat transfer from the solar cell junctions through conduction and then through convection heat transfer provides an increase in cell efficiency.

Still further embodiments of the present invention provide a rigid crystalline PVM whose construction process uses conventional technologies, as described above, but the structure of which is modified in one or more of the following ways to improve the module output efficiency:
A. A conformal hard coating is introduced on top of the top glass to allow greater amounts of the convertible light to pass through but to also limit the amount of high ultra violet and infra-red light that the solar cells convert to heat.
B. Reflective film structures designed to reflect back the light to the solar cells that lands within the module but outside or between the rigid PV solar cells within the module may be used.
C. A replacement for, or modifications to, conventional EVA back encapsulants that greatly increases the thermal conductivity of the encapsulant may be introduced, thereby increasing the efficiency of the cells and the output of the module for a given cell, and reducing the cost per installed Watt;
D. A polymeric or polymer-metal hybrid replacement for the PVF or functionally similar backsheet currently used in module manufacturing may be used, thereby greatly increasing the thermal conductivity of the encapsulant, increasing the efficiency of the cells and the output of the module for a given cell, and reducing the cost per installed Watt.

The rigid crystalline PVM may also include a micro-embossed reflective metallic or reflective coated plastic optical film of suitable design that forms a lattice, installed so that the cross-members of said lattice are between the rows and columns of solar cells in the PVM, mounted in conjunction with the solar cells between the front and rear encapsulant layers. The optical film is used to entrap the incident light that strikes the gaps between the cells in the PVM and reflects it back to the surface of the solar cells to be reabsorbed, thus increasing light conversion efficiency and, as a result, increasing the output efficiency of any given rigid cell PVM.

Alternatively, the PVM, may include a micro-embossed, solid sheet, reflective coated, plastic optical film that is mounted behind the solar cells but is mounted in conjunction with the solar cells between the front and rear encapsulant layers. A thin EVA layer is bonded to the face of the micro-embossed film to enhance bonding to the back of the PV cells. The design of the embossing is now such that the portion of the film that is visible between the cells has embossing of such a direction and angle that the light that strikes the film is reflected back onto the cells. The optical film is used to entrap the incident light that strikes the gaps between the cells in the PVM, thus increasing light conversion efficiency and, as a result, increasing the output of any given rigid cell PVM.

Alternatively, the PVM may include a micro-embossed, solid sheet, reflective coated, plastic optical film that is mounted behind rear encapsulant, thus behind the cells, taking advantage of the fact that both the cells and the back encapsulant layer, once the module has been laminated, are extremely thin. The design of the embossing is now such that the portion of the film that is visible between the cells has embossing of such a direction and angle that the light that strikes the film is reflected back onto the cells. The optical film is used to entrap the incident light that strikes the gaps between the cells in the PVM, thus increasing light conversion efficiency and, as a result, increasing the output of any given rigid cell PVM.

The reflective coated, micro embossed polymeric optical film used in any of the above-described configurations is preferably flexible, but has thermal and physical properties that allow it to retain its basic structure during the heating and pressure of the module lamination step. At the softening and flowing temperatures of EVA, the embossing structures of said optical film are not physically deformed so that the light entrapment layer of the modules used in the above-described configurations survives intact beyond the module lamination process. This film may also be ultra violet-stabilized. A typical such plastic is a member of the polycarbonate family, as this has the requisite working temperature and strength without excessive rigidity, but the present invention is not limited to the use of this material.

The micro-embossed polymeric optical film may be fabricated as continuous length roll of film using a conventional pressure roller techniques, with one of the two rollers having negative images of the micro-structures etched therein so that the micro-structures are embossed into the film during manufacturing. The non-active area of the optical film may be punched with suitably sized holes so that the EVA encapsulant or the heat conductive plastic film or the heat conductive encapsulant film or doped EVA heat conductive encapsulant located on the back side of the solar cells pass through the holes in the optical film and adhere to the back sides of the solar cells to provide adequate bonding during the lamination process.

In embodiments of a PVM configured in accordance with the present invention, different layers of the polymeric films that are initially behind the solar cells may be selectively embossed in a way that all the films, including the micro-embossed optical film, protrude to the same level of the solar cell front surface in the area between adjacent solar cells (i.e., along the width and length of the cells) without damaging the solar cells or the interconnect. This may be done by pre-forming the layers or by introducing an embossing plate that forms the structures during the lamination process.

Embodiments of the present PVM may replace the Tedlar PVF or functionally equivalent backsheet with an electrically insulating, thermally conductive polymeric film. This film provides the atmospheric and structural needs of the module in place of the PVF or similar film. This provides significant improvement in cooling by increasing the conductivity of the polymeric package in which the cells are trapped. Effective heat transfer from the solar cell junction through conduction and then through convection heat transfer is the reason for increase in cell efficiency. Alternatively, the Tedlar PVF or functionally equivalent backsheet may be replaced with (i) a composite film made of an electrically insulating, thermally conductive polymeric film deposited on an aluminum, copper or similar thermally conductive, corrosion resistant metal foil, (ii) a composite film made of an electrically insulating, thermally conductive polymeric film deposited on an aluminum, copper or similar thermally conductive, corrosion resistant metal foil, to which is bonded an aluminum honeycomb structure, or (iii) a pre-formed thermoplastic designed to allow cells and solder tabs (or, where appropriate, back-side interconnects) to fit into predesigned pockets. The thermally conductive thermoplastics may be produced from elastomeric materials with suitable additives and fillers. The electrical resistivity is typically in the range 10¹² to 10¹⁶ Ω-cm, while the thermal conductivity of thermally conductive plastics can easily exceed 10 W/mK, significantly higher than materials normally incorporated in conventional PV solar modules. The preformed thermoplastic backsheet is coated with a very thin layer of traditional EVA, providing a bonding surface for the cells and the top EVA, allowing elimination of the back EVA layer used in conventional modules.

Further, embodiments of the present PVM may replace the back EVA layer of conventional modules with a modified EVA encapsulant layer in which the EVA has been doped or modified with appropriate materials to improve the heat conduction on the back side of the cells. This enables greatly improved heat transfer while maintaining the EVA's primary purpose of encapsulation, improving the functional efficiency of the cells and the output of the module. Alternatively, the back EVA layer of the conventional modules may be replaced with an opaque encapsulant layer in which the replacement encapsulant has been doped or modified with appropriate materials to improve the heat conduction on the back side of the cells. This enables greatly improved heat transfer while maintaining the encapsulant's cell protection properties, improving the functional efficiency of the cells and the output of the module.

In some instances, a PVM according to the present invention will have a top glass layer (often, but not exclusively, made of crown glass) coated with selective frequency coatings to reduce infra-red radiation and undesirable ultraviolet light (which reduces that portion of the solar radiation spectrum that is only poorly converted to electricity, if it is converted at all). In addition, this coating may have anti-reflective properties. While a typical range that the frequency selective filtration would allow might be 450 nm to 1200 nm, the specific frequency range may be tuned for the cells to be used in the module. Multi junction cells, for example, may benefit from a broader range of available energy passed through, while black-Si cells will benefit from a lower frequency cut-off (because black-Si cells provide improved conversion efficiency in the infra-red range).

in some cases, interconnect tabs for the front half and the rear half of the PVM are of two different widths to facilitate bonding of tabs between the cells and reduce the potential for encapsulant tearing or tab “push-through” and resultant shorting during lamination. In some cases, the cross section of the interconnect tabs may be curvilinear, instead of a flat ribbon, to eliminate sharp edges, helping to avoid any potential for encapsulant tearing or tab “push-through” and resultant shorting during lamination. FIG. 10 illustrates an example of the width differential between the front half interconnect tab 1002 and rear half interconnect tab 1004. The front half and rear half tabs are bonded together in between the cells to form the interconnection. FIG. 11 illustrates differences between a cross section of a conventional interconnect tab 1102 and the cross section of an interconnect tab configured in accordance with the present invention 1104.

Various embodiments of PVMs in accordance with the present invention may include an aluminum honeycomb structure suitably bonded to an aluminum foil, so as to enhance heat transfer and lower operating temperature of the solar cells of the module.

These and other embodiments of the invention are further characterized in the claims, which follow.

What is claimed is:

1. A photovoltaic module (PVM), comprising solar cells and a micro-embossed, reflective optical film located in areas of the PVM not covered by the solar cells, said optical film configured to reflect light incident upon the PVM onto the solar cells.

2. The PVM of claim 1, wherein the micro-embossed optical film is formed from a polymeric material different than an Ethylene Vinyl Acetate (EVA) film used as encapsulant for the PVM.

3. The PVM of claim 2, wherein the optical film is characterized by not deforming at temperatures where the EVA film softens and flows.

4. The PVM of claim 3, wherein the optical film is ultra violet-stabilized.

5. The PVM of claim 3, wherein the optical film comprises Polymethyl Methacrylate (PMMA).

6. The PVM of claim 1, wherein the optical film is fabricated with optical micro-structures at locations to cover areas not covered by the solar cells in the module.

7. The PVM of claim 1, wherein the optical film is located behind the solar cells, and a non-active area of the optical film includes holes configured to allow any of an Ethylene Vinyl Acetate (EVA) encapsulant, a heat conductive plastic film, a heat conductive encapsulant film or a doped EVA heat conductive encapsulant located on back sides of the solar cells to pass there through and adhere to the back sides of the solar cells.

8. A photovoltaic module (PVM), comprising solar cells and a compliant, heat conducting polymeric film located on back sides of solar cells.

9. The PVM of claim 8, further including a heat conductive polymeric film deposited on an aluminum foil to form a composite film, which composite film comprises a rear barrier film for the PVM.

10. The PVM of claim 9, further including an aluminum honeycomb structure bonded to the aluminum foil.

11. The PVM of claim 9, further including heat conductive, polymer encapsulant films said encapsulant films having an electrical resistivity of approximately 10¹² to 10¹⁶ Ω-cm, and a thermal conductivity of approximately 1.0 W/mK to 10 W/mK.

12. A method, comprising laminating together solar cells and films of a photovoltaic module (PVM) so that layers of polymeric films which are located above back sides of the solar cells in the module are selectively embossed and so that all films in the module, including a micro-embossed optical film, protrude to a common level with front surfaces of the solar cells in areas between adjacent ones of the solar cells.

13. A photovoltaic module (PVM), comprising solar cells and one of a doped Ethylene Vinyl Acetate (EVA) encapsulant film or a modified EVA encapsulant film at back sides of the solar cells.

14. A photovoltaic module (PVM), comprising solar cells and a textured crown glass coated with selective frequency coatings on a top surface thereof.

15. A photovoltaic module (PVM), comprising solar cells interconnected by interconnect tabs, wherein those of the interconnect tabs for front halves of the solar cells are of a different width than those of the interconnect tabs for rear halves of the solar cells.

16. A photovoltaic module (PVM), comprising solar cells interconnected by interconnect tabs, wherein the interconnect tabs have a curvilinear cross-section.
